(19) United States
(12) Patent Application Publication
(10) Pub. No.: US 2025/0075334 A1
(43) Pub. Date: Mar. 6, 2025

(54) Coatings with Top Coloring Layer

(71) Applicant: Apple Inc., Cupertino, CA (US)

(72) Inventors: Brian S. Tryon, Redwood City, CA (US); Jozef M. Matlak, San Francisco, CA (US); James A. Yurko, Saratoga, CA (US)

(21) Appl. No.: 18/523,718

(22) Filed: Nov. 29, 2023

Related U.S. Application Data
(60) Provisional application No. 63/580,960, filed on Sep. 6, 2023.

(51) Int. Cl. C23C 28/04

(52) U.S. Cl. CPC C23C 28/042

(57) ABSTRACT

An electronic device may be provided with conductive structures such as a titanium housing wall. A visible-light-reflecting coating may be formed on the titanium housing wall. The coating may have adhesion and transition layers and an uppermost opaque coloring layer. In a first example, the uppermost opaque coloring layer includes CrC on a CrSiN transition layer. In a second example, the uppermost opaque coloring layer includes CrN on a CrN transition layer. The coating may exhibit a relatively uniform metallic silver or gray color that is smudge resistant even when the underlying titanium housing wall has a three-dimensional shape.

This application claims the benefit of U.S. Provisional Patent Application No. 63/580,960, filed Sep. 6, 2023, which is hereby incorporated by reference herein in its entirety.

### FIELD

This disclosure relates generally to coatings for electronic device structures and, more particularly, to visible-light-reflecting coatings for conductive electronic device structures.

### BACKGROUND

Electronic devices such as cellular telephones, computers, watches, and other devices contain conductive structures such as conductive housing structures. The conductive structures are provided with a coating that reflects particular wavelengths of light so that the conductive components exhibit a desired visible color.

It can be challenging to provide coatings such as these with a desired color brightness. In addition, if care is not taken, the coatings may exhibit unsatisfactory optical performance across different operating environments and conductive structure geometries.

### SUMMARY

An electronic device may include conductive structures such as conductive housing structures. A visible-light-reflecting coating may be formed on the conductive structures. The conductive structures may include a titanium housing wall. The coating may have adhesion and transition layers and an uppermost opaque coloring layer on the adhesion and transition layers.

In a first example, the uppermost opaque coloring layer includes CrC and the adhesion and transition layers include CrSiN. The coating may exhibit a metallic silver color in this example. In a second example, the uppermost opaque coloring layer includes CrN and the adhesion and transition layers include CrN. The coating may exhibit a metallic gray color in this example. The coating may exhibit a consistent color response even as the coating thickness changes across the underlying conductive structure. The coating may exhibit high resistance to smudging and fingerprints.

### BRIEF DESCRIPTION OF THE DRAWINGS

FIG. 1 is a perspective view of an illustrative electronic device of the type that may be provided with conductive structures and visible-light-reflecting coatings in accordance with some embodiments.

FIG. 2 is cross-sectional side view of an illustrative electronic device having conductive structures that may be provided with visible-light-reflecting coatings in accordance with some embodiments.

FIG. 3 is an exploded cross-sectional side view of an illustrative conductive housing sidewall that may be provided with a visible-light-reflecting coating in accordance with some embodiments.

FIG. 4 is a cross-sectional side view of an illustrative visible-light-reflecting coating having a top coloring layer in accordance with some embodiments.

FIG. 5 is a cross-sectional side view of an illustrative visible-light-reflecting coating having a CrC top coloring layer in accordance with some embodiments.

FIG. 6 is a plot that shows an exemplary composition (atomic percentage) at different depths through an illustrative coating of the type shown in FIG. 5 in accordance with some embodiments.

FIG. 7 is a cross-sectional side view of an illustrative visible-light-reflecting coating having a CrN top coloring layer in accordance with some embodiments.

FIG. 8 is a plot that shows an exemplary composition (atomic percentage) at different depths through an illustrative coating of the type shown in FIG. 7 in accordance with some embodiments.

### DETAILED DESCRIPTION

Electronic devices and other items may be provided with conductive structures. Coatings may be formed on the conductive structures to reflect particular wavelengths of visible light so that the conductive structures exhibit a desired color. A visible-light-reflecting coating may be deposited on a conductive structure such as a titanium housing wall. The coating may include adhesion and transition layers on the substrate and an uppermost opaque coloring layer on the adhesion and transition layers.

In a first implementation, the uppermost opaque coloring layer includes chromium carbide (CrC) and the adhesion and transition layers include a chromium silicon nitride (CrSiN) transition layer. The coating may exhibit a metallic silver color in the first implementation. In a second implementation, the uppermost opaque coloring layer includes chromium nitride (CrN) and the adhesion and transition layers include a CrN transition layer. The coating may exhibit a metallic gray color in the second implementation.

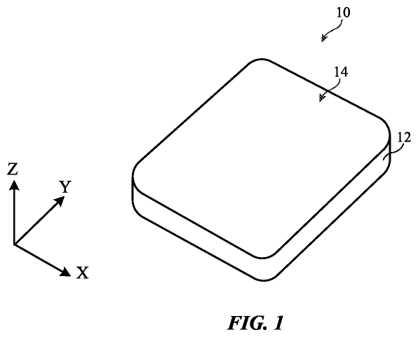

An illustrative electronic device of the type that may be provided with conductive structures and visible-light-reflecting coatings is shown in FIG. 1. Electronic device 10 of FIG. 1 may be a computing device such as a laptop computer, a computer monitor containing an embedded computer, a tablet computer, a cellular telephone, a media player, or other handheld or portable electronic device, a smaller device such as a wristwatch device (e.g., a watch with a wrist strap), a pendant device, a headphone or earpiece device, a device embedded in eyeglasses or other equipment worn on a user's head (e.g., a head mounted device such as a virtual or augmented reality headset), or other wearable or miniature device, a television, a computer display that does not contain an embedded computer, a gaming device, a navigation device, an embedded system such as a system in which electronic equipment with a display is mounted in a kiosk or automobile, a wireless base station, a home entertainment system, a wireless speaker device, a wireless access point, equipment that implements the functionality of two or more of these devices, or other electronic equipment. In the illustrative configuration of FIG. 1, device 10 is a portable device having a substantially rectangular lateral outline such as a cellular telephone or tablet computer. Other configurations may be used for device 10 if desired. The example of FIG. 1 is merely illustrative.

In the example of FIG. 1, device 10 includes a display such as display 14. Display 14 may be mounted in a housing such as housing 12. Housing 12, which may sometimes be referred to as an enclosure or case, may be formed of plastic, glass, ceramics, fiber composites, metal (e.g., stainless steel, aluminum, etc.), other suitable materials, or a combination of any two or more of these materials. Housing 12 may be formed using a unibody configuration in which some or all of housing 12 is machined or molded as a single structure or may be formed using multiple structures (e.g., an internal frame structure, one or more structures that form exterior housing surfaces, etc.). Housing 12 may have metal sidewalls or sidewalls formed from other materials. Examples of metal materials that may be used for forming housing 12 include stainless steel, aluminum, silver, gold, titanium, metal alloys, or any other desired conductive material.

Display 14 may be formed at (e.g., mounted on) the front side (face) of device 10. Housing 12 may have a rear housing wall on the rear side (face) of device 10 that opposes the front face of device 10. Conductive housing sidewalls in housing 12 may surround the periphery of device 10. The rear housing wall of housing 12 may be formed from conductive materials and/or dielectric materials.

The rear housing wall of housing 12 and/or display 14 may extend across some or all of the length (e.g., parallel to the X-axis of FIG. 1) and width (e.g., parallel to the Y-axis) of device 10. Conductive sidewalls of housing 12 may extend across some or all of the height of device 10 (e.g., parallel to Z-axis).

Display 14 may be a touch screen display that incorporates a layer of conductive capacitive touch sensor electrodes or other touch sensor components (e.g., resistive touch sensor components, acoustic touch sensor components, force-based touch sensor components, light-based touch sensor components, etc.) or may be a display that is not touch-sensitive. Capacitive touch screen electrodes may be formed from an array of indium tin oxide pads or other transparent conductive structures.

Display 14 may include an array of display pixels formed from liquid crystal display (LCD) components, an array of electrophoretic display pixels, an array of plasma display pixels, an array of organic light-emitting diode (OLED) display pixels, an array of electrowetting display pixels, or display pixels based on other display technologies.

Display 14 may be protected using a display cover layer. The display cover layer may be formed from a transparent material such as glass, plastic, sapphire or other crystalline dielectric materials, ceramic, or other clear materials. The display cover layer may extend across substantially all of the length and width of device 10, for example.

Device 10 may include one or more buttons. The buttons may be formed from a conductive button member that is located within (e.g., protruding through) openings in housing 12 or openings in display 14 (as examples). Buttons may be rotary buttons, sliding buttons, buttons that are actuated by pressing on a movable button member, etc.

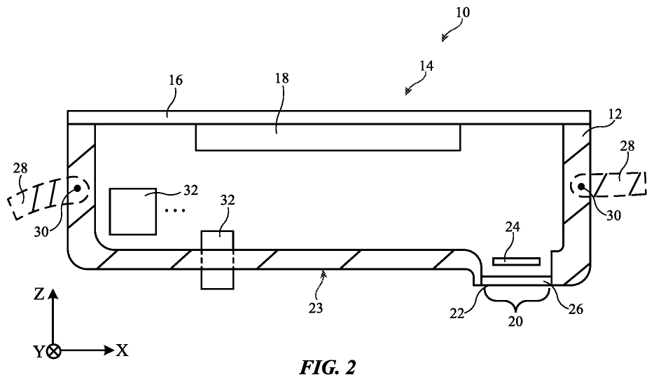

A cross-sectional side view of device 10 in an illustrative configuration in which display 14 has a display cover layer is shown in FIG. 2. As shown in FIG. 2, display 14 may have one or more display layers that form pixel array 18. During operation, pixel array 18 forms images for a user in an active area of display 14. Display 14 may also have inactive areas (e.g., areas along the border of pixel array 18) that are free of pixels and that do not produce images. Display cover layer 16 of FIG. 2 overlaps pixel array 18 in the active area and overlaps electrical components in device 10.

Display cover layer 16 may be formed from a transparent material such as glass, plastic, ceramic, or crystalline materials such as sapphire. Illustrative configurations in which a display cover layer and other transparent members in device 10 (e.g., windows for cameras and other light-based devices that are formed in openings in housing 12) are formed from a hard transparent crystalline material such as sapphire (sometimes referred to as corundum or crystalline aluminum oxide) may sometimes be described herein as an example. Sapphire makes a satisfactory material for display cover layers and windows due to its hardness (9 Mohs). In general, however, these transparent members may be formed from any suitable material.

Display cover layer 16 for display 14 may be planar or curved and may have a rectangular outline, a circular outline, or outlines of other shapes. If desired, openings may be formed in the display cover layer. For example, an opening may be formed in the display cover layer to accommodate a button, a speaker port, or other component. Openings may be formed in housing 12 to form communications or data ports (e.g., an audio jack port, a digital data port, a port for a subscriber identity module (SIM) card, etc.), to form openings for buttons, or to form audio ports (e.g., openings for speakers and/or microphones).

Device 10 may, if desired, be coupled to a strap such as strap 28 (e.g., in scenarios where device 10 is a wristwatch device). Strap 28 may be used to hold device 10 against a user's wrist (as an example). Strap 28 may sometimes be referred to herein as wrist strap 28. In the example of FIG. 2, wrist strap 28 is connected to attachment structures 30 in housing 12 at opposing sides of device 10. Attachment structures 30 may include lugs, pins, springs, clips, brackets, and/or other attachment mechanisms that configure housing 12 to receive wrist strap 28. Configurations that do not include straps may also be used for device 10.

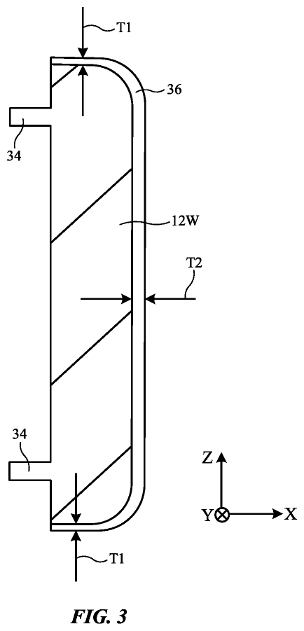

If desired, light-based components such as light-based components 24 may be mounted in alignment with an opening 20 in housing 12. Opening 20 may be circular, may be rectangular, may have an oval shape, may have a triangular shape, may have other shapes with straight and/or curved edges, or may have other suitable shapes (outlines when viewed from above). Window member 26 may be mounted in window opening 20 of housing 12 so that window member 26 overlaps component 18. A gasket, bezel, adhesive, screws, or other fastening mechanisms may be used in attaching window member 26 to housing 12. Surface 22 of window member 26 may lie flush with exterior surface 23 of housing 12, may be recessed below exterior surface 23, or may, as shown in FIG. 3, be proud of exterior surface 23 (e.g., surface 22 may lie in a plane that protrudes away from surface 23 in the −Z direction). In other words, window member 26 may be mounted to a protruding portion of housing 12. Surface 23 may, for example, form the rear face of housing 12.

Conductive structures in device 10 may be provided with a visible-light-reflecting coating that reflects certain wavelengths of light so that the conductive structures exhibit a desired aesthetic appearance (e.g., a desired color, reflectivity, etc.). The conductive structures in device 10 may include, for example, conductive portions of housing 12 (e.g., conductive sidewalls for device 10, a conductive rear wall for device 10, a protruding portion of housing 12 used to mount window member 26, etc.), attachment structures 30, conductive portions of wrist strap 28, a conductive mesh, conductive components 32, and/or any other desired conductive structures on device 10. Conductive components 32 may include internal components (e.g., internal housing members, a conductive frame, a conductive chassis, a conductive support plate, conductive brackets, conductive clips, conductive springs, input-output components or devices, etc.), components that lie both at the interior and exterior of device 10 (e.g., a conductive SIM card tray or SIM card port, a data port, a microphone port, a speaker port, a conductive button member for a ringer button, power button, volume button, or other buttons, etc.), components that are mounted at the exterior of device 10 (e.g., conductive portions of strap 28 such as a clasp for strap 28), and/or any other desired conductive structures on device 10.

FIG. 3 is an exploded cross-sectional side view of a conductive sidewall in device 10 that may be provided with a visible-light-reflecting coating. As shown in FIG. 3, housing 12 may include peripheral conductive housing structures such as conductive sidewall 12W. Conductive sidewall 12W may, for example, run around the lateral periphery of device 10 in the X-Y plane (e.g., conductive sidewall 12W may run around the periphery of display 14 of FIG. 2 and may serve as a conductive bezel for the display).

Conductive sidewall 12W may include one or more ledges 34. Ledges 34 may be used to support a conductive and/or dielectric rear wall for device 10 (e.g., at the rear face of device 10) and/or to support display cover layer 16 of FIG. 2 (e.g., at the front face of device 10). In order to provide conductive sidewall 12W with a desired visible color, a visible-light-reflecting coating such as coating 36 may be deposited onto conductive sidewall 12W (e.g., all of conductive sidewall 12W, the portions of conductive sidewall 12W at the exterior of device 10, etc.). Coating 36 may also be deposited over other conductive structures in device 10 (e.g., conductive components 32 of FIG. 2, other conductive portions of housing 12, etc.).

In practice, the coating may have different thicknesses across its surface area due to changes in the underlying geometry of the conductive structure (e.g., because of coating deposition equipment limitations in depositing uniform coatings across the underlying geometry). For example, coating 36 of FIG. 3 may exhibit a first thickness T1 at the bottom and top edges of conductive sidewall 12W (e.g., where conductive sidewall 12W exhibits a curved three-dimensional shape) but may exhibit a second thickness T2 along the center of conductive sidewall 12W (e.g., where conductive sidewall 12W exhibits a substantially planar shape). Thickness T2 may represent the maximum thickness of coating 36 across its surface area (e.g., 100% thickness). Thickness T1 may be less than thickness T2 (e.g., 30-70% of thickness T2). If care is not taken, variations in thickness along the surface area of coating 36 can undesirably alter the color of visible light reflected by the coating and thus the aesthetic appearance of the underlying conductive structure.

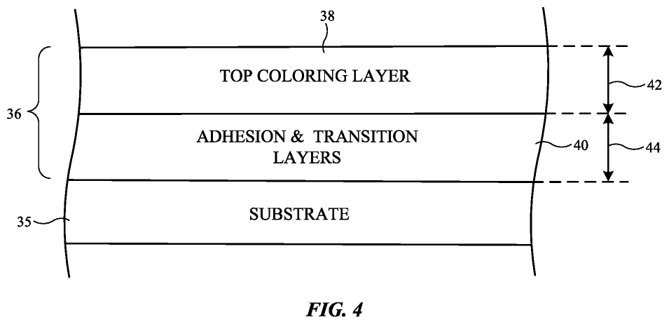

To configure a conductive structure in device 10 to exhibit a desired color across different conductive structure geometries, the conductive structure may be provided with a visible-light-reflecting coating having a top coloring layer. FIG. 4 is a cross-sectional diagram of a visible-light-reflecting coating having a top coloring layer that may be provided on conductive structures in device 10 (e.g., portions of housing 12 of FIGS. 1 and 2, conductive components 32 of FIG. 2, conductive sidewall 12W of FIG. 3, etc.).

As shown in FIG. 4, a visible-light-reflecting coating such as coating 36 may be disposed (e.g., deposited, layered, formed, etc.) on a conductive substrate such as substrate 35. Substrate 35 may be a conductive structure in device 10 such as a conductive portion of housing 12 (FIGS. 1 and 2), a conductive component 32 (FIG. 2), or conductive sidewall 12W (FIG. 3). Substrate 35 may be thicker than coating 36. The thickness of substrate 35 may be 0.1 mm to 5 mm, more than 0.3 mm, more than 0.5 mm, between 5 mm and 20 mm, less than 5 mm, less than 2 mm, less than 1.5 mm, or less than 1 mm (as examples). Substrate 35 may include stainless steel, aluminum, titanium, or other metals or alloys. In other suitable arrangements, substrate 35 may be an insulating substrate such as a ceramic substrate, a glass substrate, or substrates formed from other materials. Implementations in which substrate 35 is a titanium (Ti) substrate are described herein as an example (e.g., conductive sidewall 12W may be a titanium sidewall of device 10).

Coating 36 may include adhesion and transition layers 40 on substrate 35 and a top (uppermost) coloring layer (film) 38 on adhesion and transition layers 40. Top coloring layer 38 may, for example, have a first lateral surface that directly contacts adhesion and transition layers 40 and may have a second lateral surface opposite the first lateral surface. Adhesion and transition layers 40 may have thickness 44 (e.g., between 0.1 and 3 microns). While top coloring layer 38 is sometimes referred to herein as the uppermost or outermost layer of coating 36, an oleophobic outer layer and/or a carbon and platinum cap (not shown) may be layered on top of coating 36 if desired (e.g., layers that do not substantially contribute to the color response of coating 36).

Top coloring layer 38 may, for example, be an intrinsically-colored layer (e.g., a layer that is opaque to visible light) that preferentially absorbs incident light at particular wavelengths to reveal the color of the reflected wavelengths to an observer. The composition and/or thickness 42 of top coloring layer 38 may provide coating 36 with an intrinsic color (e.g., top coloring layer 38 may configure coating 36 to absorb and reflect light at selected wavelengths to impart coating 36 and thus substrate 35 with a desired color and reflectivity response). In another suitable arrangement, top coloring layer 38 may be a single-layer thin-film interference filter (TFIF).

The layers of coating 36 may be deposited on substrate 35 using any suitable deposition techniques. Examples of techniques that may be used for depositing the layers in coating 36 include physical vapor deposition (e.g., evaporation and/or sputtering), cathodic arc deposition, chemical vapor deposition, ion plating, laser ablation, magnetron sputtering, high impulse magnetron sputtering (HiPIMS), etc. For example, coating 36 may be deposited on substrate 35 in a deposition system having deposition equipment (e.g., a cathode). Substrate 35 may be moved (e.g., rotated) within the deposition system while the deposition equipment (e.g., the cathode) deposits the layers of coating 36. If desired, substrate 35 may be moved/rotated dynamically with respect to speed and/or orientation relative to the deposition equipment (e.g., the cathode) during deposition. This may help provide coating 36 with as uniform a thickness as possible across its area, even in scenarios where substrate 35 has a three-dimensional shape (e.g., minimizing the difference between thicknesses T1 and T2 of FIG. 3).

Through suitable selection of the composition and/or thicknesses of top coloring layer 38 and adhesion and transition layers 40, coating 36 may be configured to exhibit a desired metallic appearance and/or color response for the underlying substrate 35 (e.g., a silver or grey titanium appearance) while also reducing the production of smudges, fingerprints, or other blemishes on substrate 35 during the operating life of device 10 (e.g., relative to implementations where substrate 35 is uncoated titanium).

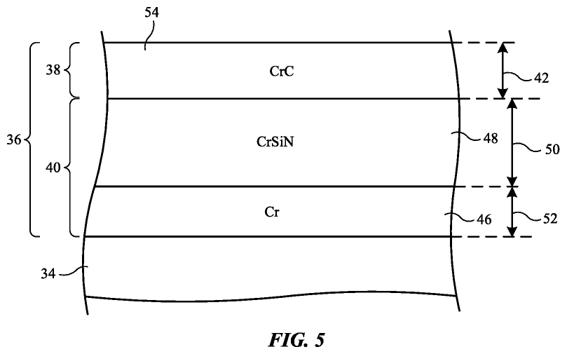

FIG. 5 is a cross-sectional side view showing an example of one such composition for coating 36. As shown in FIG. 5, adhesion and transition layers 40 may include a seed (adhesion) layer 46 on substrate 35 and one or more transition layers such as transition layer 48 on seed layer 46. Seed layer 46 may couple substrate 35 to transition layer 48 (e.g., transition layer 48 may be interposed between seed layer 46 and top coloring layer 38).

In the example of FIG. 5, seed layer 46 is formed from chromium (Cr) and may therefore sometimes be referred to herein as Cr layer 46 or Cr seed layer 46. Transition layer 48 may be formed from chromium silicon nitride (CrSiN) and may therefore sometimes be referred to herein as CrSiN layer 48 (or equivalently SiCrN layer 48). This is illustrative and non-limiting. In general, seed layer 46 and/or transition layer 48 may include chromium nitride (CrN), chromium silicon (CrSi), titanium (Ti), chromium carbide (CrC), chromium silicon nitride (CrSiN), chromium silicon carbonitride (CrSiCN), chromium silicon carbide (CrSiC), chromium carbonitride (CrCN), chromium (Cr), combinations of these, other metals, metal alloys, and/or other materials.

Seed layer 46 may have a thickness 52. Thickness 52 may be, for example, 0.1-1.0 microns, 0.1-0.5 microns, 0.05-0.75 microns, 0.2-0.3 microns, 0.1-10 microns, 0.1-0.5 microns, 0.2-0.5 microns, 0.3-0.4 microns, or other thicknesses. Transition layer 48 may have a thickness 50. Thickness 50 may be, for example, 0.15-0.25 microns, 0.1-1.0 microns, 0.05-0.75 microns, 0.05-0.7 microns, 0.1-5 microns, 0.2-0.9 microns, or other thicknesses less than thickness 42 (e.g., at the location where coating 36 exhibits peak thickness).

In the example of FIG. 5, top coloring layer 38 includes a single layer 54 that includes chromium and carbon (e.g., chromium carbide (CrC). Layer 54 is therefore sometimes also referred to herein as CrC layer 54. CrC layer 54 may have thickness 42. Thickness 42 may be relatively large. For example, thickness 42 may be 375-475 nm, 300-500 nm, 200-600 nm, 200-450 nm, 100-700 nm, 390-440 nm, greater than 400 nm, greater than 300 nm, greater than 200 nm, less than 450 nm, less than 500 nm, less than 600 nm, or other thicknesses (e.g., at the location where coating 36 exhibits peak thickness). Transition layer 48 may have thickness 50. Thickness 50 may be 350-450 nm, 300-500 nm, 200-600 nm, 100-700 nm, greater than 400 nm, greater than 300 nm, greater than 200 nm, less than 450 nm, less than 500 nm, less than 600 nm, less than 700 nm, or other thicknesses greater than thickness 46 (e.g., at the location where coating 36 exhibits peak thickness).

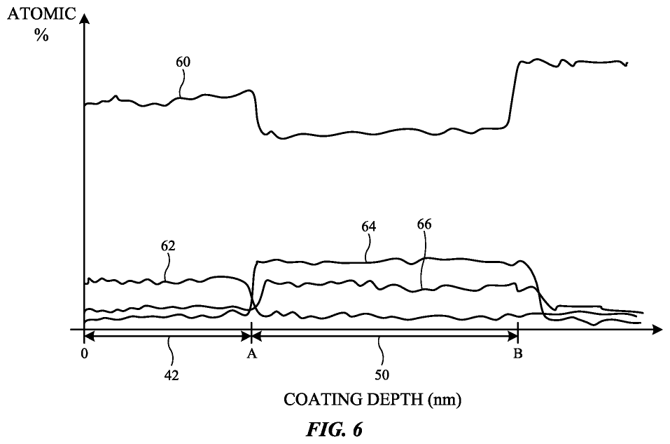

FIG. 6 is a plot of the elemental composition of the layers of coating 36 of FIG. 5. The curves of FIG. 6 are generated using an energy dispersive spectroscopy (EDS) line scan that measures the atomic percentage of different elements at different depths from the exterior surface and through the thickness of coating 36 (e.g., at different coating depths relative to the upper (outer) surface of CrC layer 54).

As shown in FIG. 6, curve 60 plots the atomic percentage (%) of chromium (Cr) atoms through the thickness of coating 36. Curve 64 plots the atomic percentage of silicon (Si) atoms through the thickness of coating 36. Curve 62 plots the atomic percentage of carbon (C) atoms through the thickness of coating 36. Curve 66 plots the atomic percentage of nitrogen (N) atoms through the thickness of coating 36.

As shown by curve 60, coating 36 exhibits a relatively high percentage (e.g., a peak) of Cr atoms within CrC layer 54 of FIG. 5 (e.g., within the uppermost layer of the coating located between a depth of 0 nm and depth A, where thickness 42 is given by the magnitude of depth A) and within seed layer 46 of FIG. 5 (e.g., at depths greater than depth B). As shown by curve 64, coating 36 exhibits a relatively high percentage (e.g., peaks) of Si atoms within CrSiN layer 48 of FIG. 5 (e.g., at depths between depth A and depth B, where the thickness 50 of CrSiN layer 48 is given by the difference between depths A and B). As shown by curve 62, coating 36 exhibits a relatively high percentage (e.g., peaks) in C atoms within CrC layer 54 of FIG. 5. Finally, as shown by curve 66, coating 36 exhibits a relatively high percentage (e.g., a peak) in N atoms within CrSiN layer 48 of FIG. 5.

As shown by curves 60 and 62, CrC layer 54 may include a greater percentage of Cr atoms than C atoms. For example, the atomic percentage of Cr atoms within CrC layer 54 may be 70-80%, 60-90%, 50-95%, 65-85%, greater than 70%, greater than 60%, greater than 50%, less than 80%, less than 85%, less than 90%, or other amounts. The remainder of the atomic percentage of CrC layer 54 may be C atoms. For example, the atomic percentage of C atoms within CrC layer 54 may be 10-20%, 5-25%, 5-35%, 5-50%, greater than 10%, greater than 5%, less than 20%, less than 30%, less than 50%, or other amounts.

As shown by curves 60, 64, and 66, CrSiN layer 48 may include a greater percentage of Cr atoms than Si atoms and may include a greater percentage of Si atoms than N atoms. CrSiN layer 48 may have a lower atomic percentage of Cr atoms than CrC layer 54 if desired. For example, the atomic percentage of Cr atoms within CrSiN layer 48 may be 60-70%, 50-80%, 50-85%, 55-90%, greater than 60%, greater than 55%, greater than 50%, less than 70%, less than 75%, less than 80%, less than 90%, or other amounts. The atomic percentage of Si atoms within CrSiN layer 48 may be 10-20%, 10-30%, 5-25%, 5-40%, greater than 15%, greater than 10%, greater than 5%, less than 20%, less than 25%, less than 30%, less than 40%, or other values. The remainder of the atomic percentage of CrSiN layer 48 may be N atoms. For example, the atomic percentage of N atoms within CrSiN layer 48 may be 1-10%, 1-15%, 5-15%, 1-20%, greater than 5%, greater than 2%, less than 15%, or other amounts.

When configured in this way, coating 36 may exhibit a robust metallic silver color that is relatively constant as the overall thickness of coating 36 varies (e.g., when the underlying substrate 35 has a three-dimensional shape) and that is resistant to smudges and fingerprints. For example, at a location along the lateral area of coating 36 at which coating 36 exhibits peak/maximum thickness, when viewed at an angle of zero degrees relative to a normal axis/surface of the lateral area of coating 36, coating 36 of FIG. 5 may exhibit an L* value (in an L*a*b* color space) of greater than 80, greater than 70, greater than 60, less than 90, less than 95, 80-90, 70-95, 60-95, 81-93, or other L* values, an a* value (in the L*a*b* color space) of −5-5, −2-5, −1-1, −3-8, −10-10, 0-1, greater than −1, greater than −2, greater than −5, less than 1, less than 2, less than 5, or other a* values, and a b* value (in the L*a*b* color space) of −5-5, −10-10, less 0, less than 5, greater than −5, greater than −10, or other b* values.

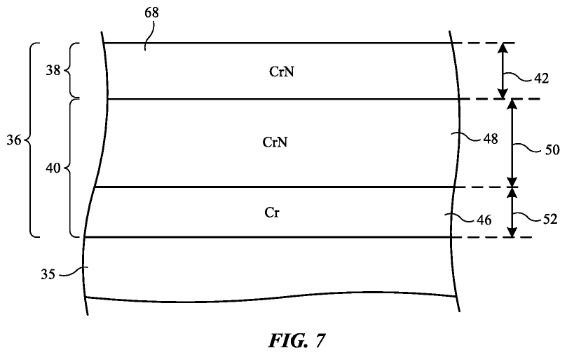

The example of FIG. 5 in which top coloring layer 38 includes CrC and transition layer 48 includes CrSiN is merely illustrative. FIG. 7 is a cross-sectional side view showing another example in which top coloring layer 38 includes chromium and nitrogen (e.g., chromium nitride (CrN)). As shown in FIG. 7, transition layer 48 is also formed from chromium nitride (CrN) and may therefore sometimes be referred to herein as CrN layer 48. This is illustrative and non-limiting. In general, seed layer 46 and/or transition layer 48 may include chromium nitride (CrN), chromium silicon (CrSi), titanium (Ti), chromium carbide (CrC), chromium silicon nitride (CrSiN), chromium silicon carbonitride (CrSiCN), chromium silicon carbide (CrSiC), chromium carbonitride (CrCN), chromium (Cr), combinations of these, other metals, metal alloys, and/or other materials.

Seed layer 46 may have a thickness 52. Thickness 52 may be, for example, 0.1-1.0 microns, 0.1-0.5 microns, 0.05-0.75 microns, 0.2-0.3 microns, 0.1-10 microns, 0.1-0.5 microns, 0.2-0.5 microns, 0.3-0.4 microns, or other thicknesses. Transition layer 48 may have a thickness 50. Thickness 50 may be, for example, 0.15-0.25 microns, 0.1-1.0 microns, 0.05-0.75 microns, 0.05-0.7 microns, 0.1-5 microns, 0.2-0.9 microns, or other thicknesses (e.g., less than thickness 42).

In the example of FIG. 7, top coloring layer 38 includes a single layer 68 that includes chromium and nitrogen (e.g., chromium nitride (CrN)). Layer 68 is therefore sometimes also referred to herein as CrN layer 68. CrN layer 68 may have a relatively high amount of nitrogen (e.g., more nitrogen than CrN layer 48). CrN layer 48 may have more chromium than CrN layer 68.

CrN layer 68 may have thickness 42. Thickness 42 may be relatively large. For example, thickness 42 may be 150-300 nm, 100-400 nm, 90-500 nm, 100-250 nm, 100-500 nm, greater than 100 nm, greater than 120 nm, greater than 150 nm, less than 300 nm, less than 400 nm, less than 500 nm, or other thicknesses (e.g., at the location where coating 36 exhibits peak thickness).

CrN layer 48 may have thickness 50. Thickness 50 may be 500-700 nm, 400-800 nm, 550-650 nm, 300-900 nm, greater than 500 nm, greater than 400 nm, less than 600 nm, less than 700 nm, less than 90 nm, or other thicknesses greater than thickness 42 (e.g., at the location where coating 36 exhibits peak thickness).

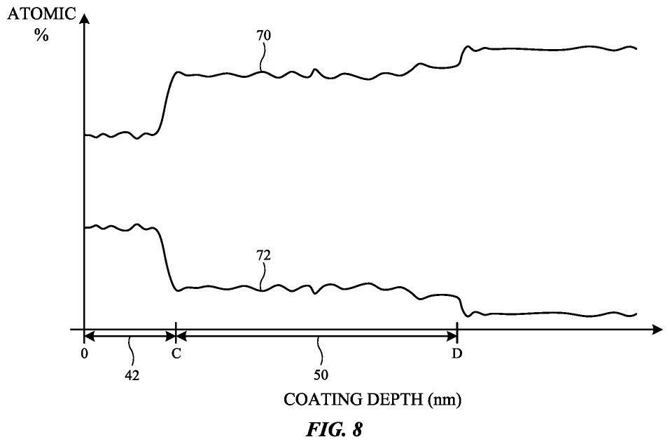

FIG. 8 is a plot of the elemental composition of the layers of coating 36 of FIG. 7. The curves of FIG. 8 are generated using an energy dispersive spectroscopy (EDS) line scan that measures the atomic percentage of different elements at different depths from the exterior surface and through the thickness of coating 36 (e.g., at different coating depths relative to the upper (outer) surface of CrN layer 68).

As shown in FIG. 8, curve 70 plots the atomic percentage (%) of chromium (Cr) atoms through the thickness of coating 36. Curve 72 plots the atomic percentage of nitrogen (N) atoms through the thickness of coating 36.

As shown by curve 70, coating 36 exhibits a relatively high percentage (e.g., a peak) of Cr atoms within CrN layer 48 of FIG. 7 (e.g., between depth C and depth D, where thickness 50 is given by the difference between depths C and D) and within seed layer 46 of FIG. 7 (e.g., at depths greater than depth D). As shown by curve 72, coating 36 exhibits a relatively high percentage (e.g., peaks) of N atoms within CrN layer 68 (e.g., within the uppermost layer of coating 36 at depths between a depth of zero and depth C, where the thickness 42 of CrN layer 68 is given by the magnitude of depth 42).

As shown by curves 70 and 72, CrN layer 68 may include a greater percentage of Cr atoms than N atoms and may include a greater percentage of N atoms than CrN layer 48. On the other hand, CrN layer 48 may include a greater percentage of Cr atoms than N atoms, a greater percentage of Cr atoms than CrN layer 68, and a smaller percentage of N atoms than CrN layer 68.

For example, the atomic percentage of Cr atoms within CrN layer 68 may be 50-70%, 55-65%, 45-75%, greater than 55%, greater than 50%, less than 65%, less than 70%, less than 75%, or other values. The remainder of the atomic percentage of CrN layer 68 may be N atoms. For example, the atomic percentage of N atoms within CrN layer 68 may be 20-30%, 20-40%, 15-40%, 10-40%, greater than 10%, greater than 20%, greater than 15%, less than 30%, less than 40%, less than 50%, or other amounts.

The atomic percentage of Cr atoms within CrN layer 48 may, for example, be 70-80%, 65-90%, 60-95%, greater than 70%, greater than 60%, greater than 50%, less than 85%, less than 90%, less than 95%, or other values. The remainder of the atomic percentage of CrN layer 48 may be N atoms. For example, the atomic percentage of N atoms within CrN layer 48 may be 1-10%, 2-15%, 3-20%, greater than 5%, greater than 1%, less than 10%, less than 15%, less than 20%, or other amounts.

When configured in this way, coating 36 may exhibit a robust metallic gray color that is relatively constant as the overall thickness of coating 36 varies (e.g., when the underlying substrate 35 has a three-dimensional shape) and that is resistant to smudges and fingerprints. For example, at a location along the lateral area of coating 36 at which coating 36 exhibits peak/maximum thickness, when viewed at an angle of zero degrees relative to a normal axis/surface of the lateral area of coating 36, coating 36 of FIG. 7 may exhibit an L* value (in an L*a*b* color space) of greater than 60, greater than 50, greater than 45, less than 65, less than 70, less than 80, 60-70, 55-75, 50-80, or other L* values, an a* value (in the L*a*b* color space) of −5-5, −2-5, −1-1, −3-8, −10-10, −1-0, greater than −1, greater than −2, greater than −5, less than 1, less than 2, less than 5, or other a* values, and a b* value (in the L*a*b* color space) of −5-5, −10-10, less 10, greater than −5, greater than −10, or other b* values.

Coating 36 of FIGS. 5 and 7 may be provided with a textured outer surface if desired. The outer surface may, for example, be polished, brushed, and/or blasted to exhibit a desired texture after coating 36 has been deposited on substrate 35.

The examples of FIGS. 5 and 7 are merely illustrative. Additional elements may be included in one or more of the layers of coating 36. The layers may be arranged in other orders. The layers may have different thicknesses or compositions. The coating may have other color profiles and angular responses. The layers described herein may sometimes also be referred to as films. In a first additional implementation, top coloring layer 38 is a CrSiCN layer and transition layer 48 is a CrSiN layer. In a second additional implementation, top coloring layer 38 is a CrN layer and transition layer 48 is a CrC layer.

Device 10 may gather and/or use personally identifiable information. It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The foregoing is merely illustrative and various modifications can be made to the described embodiments. The foregoing embodiments may be implemented individually or in any combination.

What is claimed is:

1. Apparatus comprising:
a conductive substrate; and
a coating on the conductive substrate and having a color, the coating comprising:
a seed layer,
a CrSiN layer on the seed layer, and
a CrC layer on the CrSiN layer, wherein the CrC layer is an uppermost layer of the coating.

2. The apparatus of claim 1, wherein the conductive substrate comprises titanium.

3. The apparatus of claim 1, wherein the CrSiN layer directly contacts the Cr layer and the CrC layer.

4. The apparatus of claim 3, wherein the seed layer comprises chromium.

5. The apparatus of claim 3, wherein the CrC layer is at least 200 nm thick, the CrSiN layer is at least 400 nm thick, and the seed layer is thinner than the CrC layer.

6. The apparatus of claim 3, wherein the CrC layer has a higher atomic percentage of chromium atoms than the CrSiN layer.

7. The apparatus of claim 6, wherein an atomic percentage of Cr atoms in the CrSiN layer is greater than 50%.

8. The apparatus of claim 1, wherein an atomic percentage of Cr atoms in the CrC layer is greater than 60% and an atomic percentage of Si atoms in the CrSiN layer is greater than 10%.

9. The apparatus of claim 1 wherein, at a location of maximum thickness and a viewing angle of zero degrees relative to a normal axis of the coating, the coating has an L* value greater than 70, an a* value between −10 and 10, and a b* value between −10 and 10.

10. Apparatus comprising:
a conductive substrate; and
a coating on the conductive substrate and having a color, the coating comprising:
a seed layer,
a first CrN layer on the seed layer, and
a second CrN layer on the first CrN layer, wherein the second CrN layer is an uppermost layer of the coating.

11. The apparatus of claim 10, wherein the conductive substrate comprises titanium.

12. The apparatus of claim 10, wherein the first CrN layer directly contacts the seed layer and the second CrN layer.

13. The apparatus of claim 12, wherein the first CrN layer is at least 100 nm thick and the second CrN layer is at least 300 nm thick.

14. The apparatus of claim 10, wherein the first CrN layer has a higher atomic percentage of chromium atoms than the second CrN layer.

15. The apparatus of claim 10, wherein the second CrN layer has a higher atomic percentage of nitrogen atoms than the first CrN layer.

16. The apparatus of claim 10, wherein an atomic percentage of Cr atoms in the first CrN layer is greater than 70% and an atomic percentage of Cr atoms in the second CrN layer is greater than 50%.

17. The apparatus of claim 10 wherein, at a location of maximum thickness and a viewing angle of zero degrees relative to a normal axis of the coating, the coating has an L* value greater than 50, an a* value between −5 and 5, and a b* value between −10 and 10.

18. An electronic device comprising:
a titanium housing wall; and
a coating on the titanium housing wall and having a color, the coating comprising:
adhesion and transition layers, and
an uppermost layer on the adhesion and transition layers, wherein the uppermost layer comprises chromium nitride (CrN).

19. The electronic device of claim 18, wherein the adhesion and transition layers comprise a chromium seed layer and a CrN transition layer on the chromium seed layer.

20. The electronic device of claim 19, wherein the CrN transition layer directly contacts the uppermost layer and the chromium seed layer, the uppermost layer is at least 100 nm thick, the CrN transition layer is at least 400 nm thick, the chromium seed layer is at least 100 nm thick, an atomic percentage of chromium atoms in the CrN transition layer is greater than 70%, an atomic percentage of chromium atoms in the uppermost layer is less than the atomic percentage of chromium atoms in the CrN transition layer, and an atomic percentage of nitrogen atoms in the uppermost layer is between 10% and 40%.
